(19) United States
(12) Patent Application Publication
(10) Pub. No.: US 2006/0093005 A1
(43) Pub. Date: May 4, 2006

(54) Semiconductor laser

(75) Inventors: Yuichiro Okunuki, Tokyo (JP); Hiromasu Matsuoka, Hyogo (JP)

Correspondence Address: LEYDIG VOIT & MAYER, LTD, 700 THIRTEENTH ST. NW, SUITE 300, WASHINGTON, DC, 20005-3960, US

(73) Assignee: Mitsubishi Denki Kabushiki Kaisha, Tokyo (JP)

(21) Appl. No.: 11/212,592

(22) Filed: Aug. 29, 2005

(30) Foreign Application Priority Data
Oct. 29, 2004 (JP) 2004-316393

(51) Int. Cl. H01S 5/00

(52) U.S. Cl. 372/49.01

(57) ABSTRACT

A semiconductor laser has at least one laser-beam-emitting surface including a multilayer dielectric film composed of layers of different dielectric materials. The multilayer dielectric film has a wavelength dependent reflectance with a maximum or minimum in the vicinity of the oscillation wavelength of the laser. The reflectance of the laser-beam-emitting surface at the oscillation wavelength of the laser is at least 10% and not more than 25%.

### BACKGROUND OF THE INVENTION

1. Field of the Invention

The present invention relates to a semiconductor laser the laser-beam-emitting end face of which is provided with a dielectric multilayer film.

2. Description of Related Art

A Fabry-Perot laser diode (hereinafter, referred to as FP-LD) produces laser oscillation by the travel and resonance of light between two reflecting surfaces forming a pair. In general, this reflecting surface is formed by cleaving a crystal. When the reflectance of the one end face (front end face) of the cleavage planes, serving as a laser-beam-emitting plane, is R_{f}, and the reflectance of the other end face (rear end face) thereof is Rᵣ, it is usually designed so that R_{f} is smaller than Rᵣ. Such a constitution of a laser diode (hereinafter, referred to as LD) can take more laser beams from the front end face, thus advantageously increasing the slope-efficiency, which is an important property for an LD.

Meanwhile, the reflectance of the end face also affects the threshold current, which is another important property for the LD. As the mirror loss given by 1/(2 L)×ln{1/(R_{f}Rᵣ)} is larger, the threshold current is higher. Herein, L is the length of the resonator of the LD. The phenomenon in which this threshold current increases is remarkable at an elevated temperature. In the FP-LD used in a wide temperature range, it is undesirable to design R_{f}Rᵣ with an excessively small value. In general, in the FP-LD used in a wide temperature range, R_{f}Rᵣ is designed so that R_{f}=approximately 30%, and Rᵣ=60-95% around. At that time, the front end face is often coated with a dielectric single-layer film (commonly, Al₂O₃, SiO₂, or SiNₓ film) having a thickness of λ/2 (λ is the in-medium wavelength of the oscillating light of the LD). This is because these dielectric films protect the crystal material of the LD, and further, a stable reflectance of approximately 30 percent can be thereby easily obtained. The reason why the stable reflectance is obtained is as follows.

It is known that a transparent film having a thickness of λ/2 has no optical influence. The reflectance of the end face is determined by the refractive index of the semiconductor material constituting the LD and the refractive index of air. For example, in a 1.3 μm-band InP LD, the reflectance of the front end face thereof is about 27%. The calculation results of the wavelength dependence of the reflectance in this case are shown in FIG. 6. As is evident therefrom, the reflectance thereof is the maximum in the vicinity of the oscillation wavelength (1.3 μm) of the LD, and a stable reflectance is obtained over a wide range of wavelengths. This means that the stable reflectance is obtained against variations in the oscillation wavelength of the LD and variations in the thickness and refractive index of the dielectric film layer.

Laser diodes include, as another technology, a distributed feedback laser diode (hereinafter, referred to as a DFB-LD) in which a diffraction grating is provided within its laser resonator. The reflectance of the front end face of the DFB-LD is typically designed to be smaller than or equal to 3%. However, for example, JP-A-2003-133638 discloses that the front end face having a reflectance of 10% or more can reduce the noise caused by the returning light reflected from the outside of a LD. This literature describes that a reflectance of 10-20% is achieved by forming the front end face of a dielectric single-layer film formed of SiNₓ.

In the conventional semiconductor laser, the FP-LD cannot achieve high slope-efficiency because of the high reflectance of its front end face on the order of 30%. It is effective for enhancing the slope-efficiency to lower the reflectance of the front end face; however, because too small reflectance makes the threshold current too high, the optimum reflectance is on the order of 10-25%. However, if an attempt to obtain such a reflectance by use of a conventional dielectric single-layer film is made, the dielectric film should be formed in the area where the wavelength dependence of the reflectance is large. This is because, for example, in the case of a 1.3 μm-band LD, the wavelength dependence of the reflectance is large as shown in FIG. 7. As a result, there is a problem that the property of the LD varies widely because a stable reflectance cannot be obtained against variations in the oscillation wavelength of the LD and variations in the thickness and refractive index of the dielectric film. Further, also in the DFB-LD disclosed by the above JP-A-2003-133638, there is a problem similar to the one in the case of the above-mentioned FP-LD because the attempt to achieve a reflectance of 10-20% by use of a dielectric single-layer film is made in the DFB-LD.

Meanwhile, for example, JP-A-08-298351 discloses a technology such that over the beam-emitting end face of the resonator of which the semiconductor layer is subjected to cleaving or etching, a dielectric-multilayer-reflection film the outermost layer of which is formed of MgF₂, and the layers other than the outermost layer of which contain one or more types of oxide dielectric materials as constituents is formed. However, this dielectric-multilayer-reflection film is provided to prevent the properties of the LD from varying with time, not to accomplish the aim of performing high slope-efficiency with reducing variations of the properties, or reducing noise due to returning light.

### SUMMARY OF THE INVENTION

The present invention has been accomplished to solve the above-mentioned problem. An object of the present invention is to provide a semiconductor laser such as an FP-LD exhibiting a narrow range of property variation and having high slope-efficiency, or a DFB-LD in which noise due to returning light can be reduced.

The semiconductor laser according to the present invention is the semiconductor laser at least one laser-beam-emitting surface of which is provided with a dielectric film, the dielectric film being formed of the multilayer film of a plurality of types of dielectric materials, which is arranged such that the wavelength dependence of the reflectance of the emitting surface is the maximum or minimum in the vicinity of the oscillation wavelength of the laser and further, the reflectance of the emitting surface in the oscillation wavelength thereof is 10% or more and 25% or less.

According to the present invention, because the end-face-dielectric-film-structure in which a stable reflectance can be obtained against variations in the oscillation wavelength of the LD and variations in the thickness and refractive index of the dielectric film is formed, the following semiconductor laser is obtained: in an FP-LD, the range of property variation is narrow, and high slope-efficiency is obtained, while in a DFB-LD, noise due to returning light can be reduced.

### BRIEF DESCRIPTION OF THE DRAWINGS

FIG. 1 is a sectional view showing the basic structure of a semiconductor laser in accordance with embodiment 1 of the present invention;

FIG. 2 is an explanatory diagram showing the wavelength dependence of the reflectance in the multilayer film in accordance with the embodiment 1 of the invention;

FIG. 3 is a sectional view showing the basic structure of a semiconductor laser in accordance with embodiment 2 of the invention;

FIG. 4 is an explanatory diagram showing the wavelength dependence of the reflectance in the multilayer film in accordance with the embodiment 2 of the invention;

FIG. 5 is a sectional view showing the basic structure of a semiconductor laser in accordance with embodiment 3 of the invention;

FIG. 6 is an explanatory diagram showing the relationship between the reflectance of the front end face of a conventional laser diode and the wavelength; and

FIG. 7 is an explanatory diagram showing the wavelength dependence of the reflectance achieved by the dielectric single-layer film of a conventional 1.3-μm-band laser diode.

### DETAILED DESCRIPTION OF THE PREFERRED EMBODIMENTS

An embodiment of the present invention will now be described in details by reference to the drawings.

### Embodiment 1

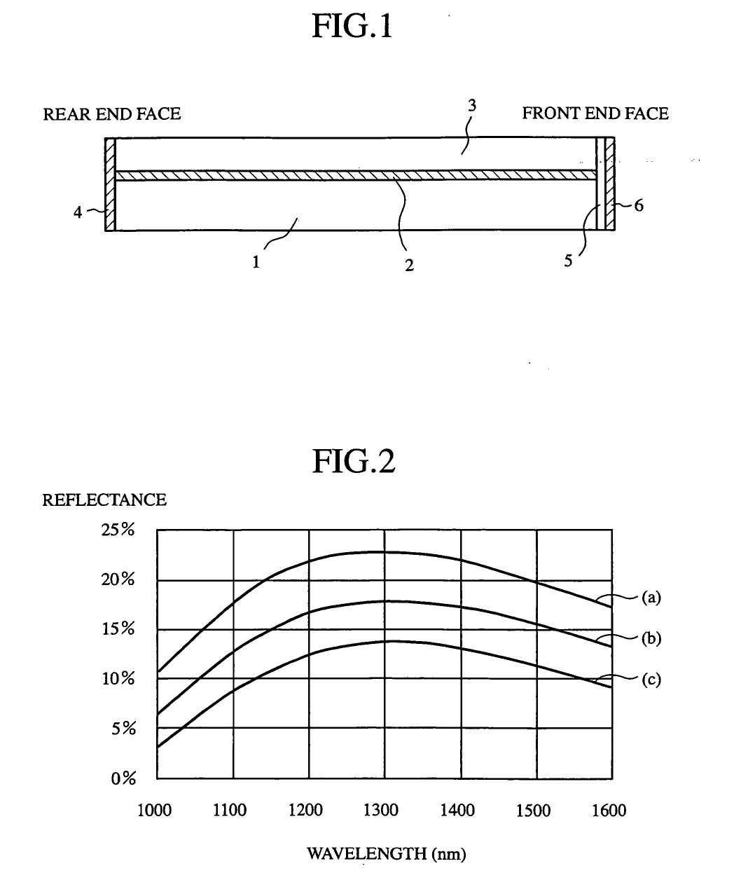

FIG. 1 is a sectional view showing the basic structure of a semiconductor laser in accordance with embodiment 1 of the present invention.

Referring to FIG. 1, reference numeral 1 denotes a p-type InP substrate; 2 denotes an active layer formed of InGaAsP; and 3 denotes a clad layer formed of n-type InP. The active layer 2 herein is depicted as a single layer; however, the active layer 2 may include multiple quantum wells. Further, the top and bottom of the active layer 2 each may be provided with a light confining layer adjusting the field distribution of light. In the example shown in the figure, the conduction type of the substrate 1 is of p-type; however, the semiconductor laser may have a structure in which an active layer and a p-type InP clad layer are provided on a n-type InP substrate, its polarity being reversed. The rear end face thereof is provided with a multilayer-high-reflection film 4 having a reflectance of about 90%, formed of SiO₂, Si, and Al₂O₃. The front end face thereof serving as a laser-beam-emitting surface is provided with a multilayer film formed of a first dielectric film 5 and a second dielectric film 6.

Some examples of the constitution of the dielectric multilayer film formed over the front end face will now be described.

(a) A constitution using an Al₂O₃ film (refractive index: 1.65) having a thickness of λ/8, serving as the first dielectric film 5, and using a SiO₂ film (refractive index: 1.45) having a thickness of λA/8, serving as the second dielectric film 6.

(b) A constitution using an Al₂O₃ film having a thickness of λ/4, serving as the first dielectric film 5, and using a SiO₂ film having a thickness of λ/4, serving as the second dielectric film 6.

(c) A constitution using a SiNₓ film (refractive index: 2.0) having a thickness of λ/4, serving as the first dielectric film 5, and using an Al₂O₃ film having a thickness of λ/4, serving as the second dielectric film 6.

Herein, λ is the in-medium wavelength of the oscillating light of the LD in each of the dielectric materials, and is given by λ₀/nᵣ when the emission wavelength of the LD is λ₀ and the refractive index of the dielectric material is nᵣ. When the refractive index and the film thickness of the dielectric film 5 are n₅ and d₅, respectively, and the refractive index and the film thickness of the dielectric film 6 are n₆ and d₆, respectively, it is necessary, in any example, to determine the film thickness such that the relation expressed by the following equation (1) is satisfied.
mλ₀/4=n₅d₅+n₆d₆ (m is an integer of one or more) (1)
All of the above three examples are the ones where m=2.

The wavelength dependences of the reflectances of the above three types of multilayer films are shown in FIG. 2. Although these examples are shown with respect to the case of the 1.3-μm-band LD, similar results are obtained in the cases of other-wavelength-band LDs. The reflectances thereof in the case where the oscillation wavelength is 1.3 μm are 23% for Example (a), 18% for Example (b), and 14% for Example (c), respectively. In all the examples, the reflectance is the maximum in the vicinity of the oscillation wavelength, and a stable reflectance can be obtained against variations in the oscillation wavelength of the LD and variations in the thickness and refractive index of the dielectric film. Additionally, when the wavelength dependence of the reflectance is the minimum, the reflectance is 10% or more (not depicted).

The slope-efficiency η of the FP-LD can be represented by the following equation (2) by means of using the reflectance R_{f} of the front end face, the reflectance Rᵣ of the rear end face, and the sum of the slope-efficiencies ηₜₒₜₐₗ of both of the faces of the LD.

$$η = {η}_{total} ( \frac{1}{1 + \sqrt{\frac{{R}_{f}}{{R}_{r}} ( \frac{1 - {R}_{r}}{1 - {R}_{f}} )}} ) \qquad ( 2 )$$

Therefore, the slope-efficiencies can be improved by 5% for the above Example (a), by 12% for Example (b), and by 19% for Example (c), respectively, as compared with the case of the conventional dielectric single-layer film of the film thickness λ/2 (reflectance: 27%).

As mentioned above, according to the embodiment 1, the laser-beam-emitting surface formed by means of cleavage is provided with a multilayer film formed of two layers of a plurality of types of dielectric materials, arranged such that the wavelength dependence of the reflectance of the emitting surface is the maximum in the vicinity of the oscillation wavelength of the LD and the reflectance of the emitting surface in the oscillation wavelength of the LD is 23%, 18%, or 14%. Therefore, the reflectance is the maximum in the vicinity of the oscillation wavelength, and a stable reflectance can be obtained against variations in the oscillation wavelength of the LD and variations in the thickness and refractive index of the dielectric film. In addition, it is preferred that the reflectance of the emitting surface can be arranged to be 10% or more and 25% or less.

### Embodiment 2

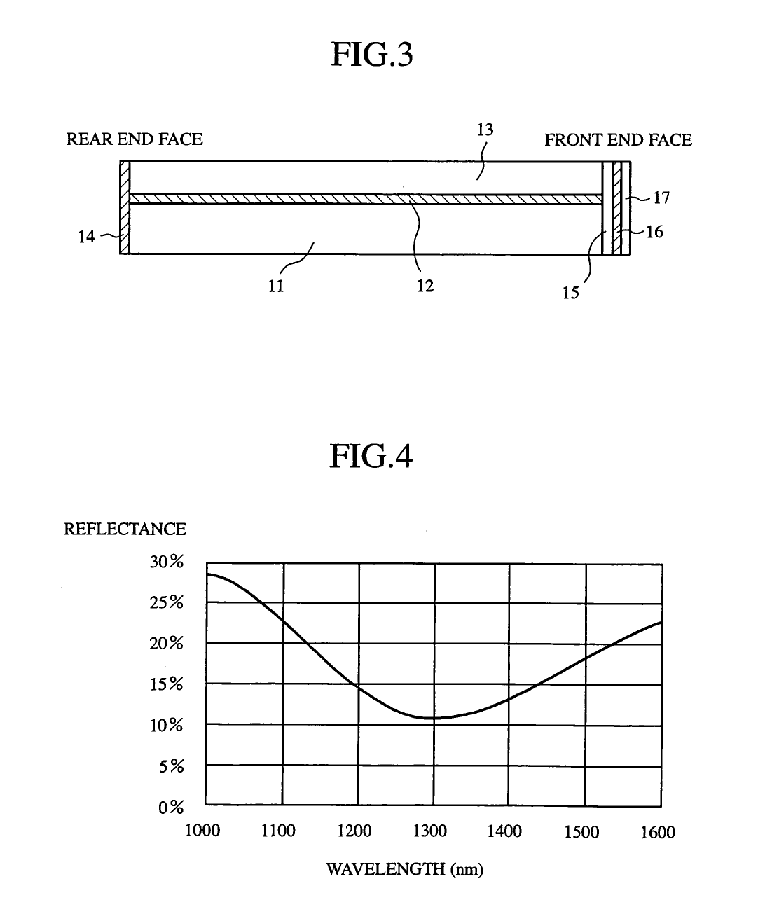

FIG. 3 is a sectional view showing the basic structure of a semiconductor laser according to embodiment 2 of the present invention.

Referring to FIG. 3, reference numeral 11 denotes a p-type InP substrate, 12 denotes an active layer formed of InGaAsP, and 13 denotes a clad layer formed of n-type InP. The reflection film 14 formed over the rear end face is a multilayer-high-reflection film having the same constitution as that of the reflection film in the above embodiment 1. The front end face thereof serving as the laser-beam-emitting surface is provided with a multilayer film of a plurality of types of dielectric materials, formed of a first dielectric film 15, a second dielectric film 16, and a third dielectric film 17. An example having the constitution of this multilayer film uses a SiO₂ film having a thickness of λ/4 (λ is the in-medium wavelength of the oscillating light of the LD) as the first dielectric film 15, an Al₂O₃ film having a thickness of λ/4 as the second dielectric film 16, and a SiO₂ film having a thickness of λ/4 as the third dielectric film 17. Herein, when the refractive index and the film thickness of the dielectric film 15 are n₁₅ and d₁₅, respectively, the refractive index and the film thickness of the dielectric film 16 are n₁₆ and d₁₆, respectively, and the refractive index and the film thickness of the dielectric film 17 are n₁₇ and d₁₇, respectively; the relational expression corresponding to the above equation (1) and determining the film thicknesses is given by the following equation (3):
mλ₀/4=n₁₅d₁₅+n₁₆d₁₆+n₁₇d₁₇ (m is an integer of one or more) (3)
The above example is the one where m=3.

The wavelength dependence of the reflectance of the multilayer film in the case of the above example is shown in FIG. 4. Although the result in the case of the 1.3-μm-band LD is shown, similar results are obtained in the cases of other-wavelength-band LDs. The reflectance in the case where the oscillation wavelength is 1.3 μm is 11%. The reflectance is the minimum in the vicinity of the oscillation wavelength, and a stable reflectance can be obtained against variations in the oscillation wavelength of the LD and variations in the thickness and refractive index of the dielectric film.

As mentioned above, according to the embodiment 2, the laser-beam-emitting surface formed by means of cleavage is provided with a multilayer film formed of three layers of a plurality of types of dielectric materials, arranged such that the wavelength dependence of the reflectance of the emitting surface is the minimum in the vicinity of the oscillation wavelength of the LD and the reflectance of the emitting surface in the oscillation wavelength of the LD is 11%. Therefore, the reflectance is the minimum in the vicinity of the oscillation wavelength, and a stable reflectance can be obtained against variations in the oscillation wavelength of the LD and variations in the thickness and refractive index of the dielectric film, similarly as in the case of the embodiment 1.

### Embodiment 3

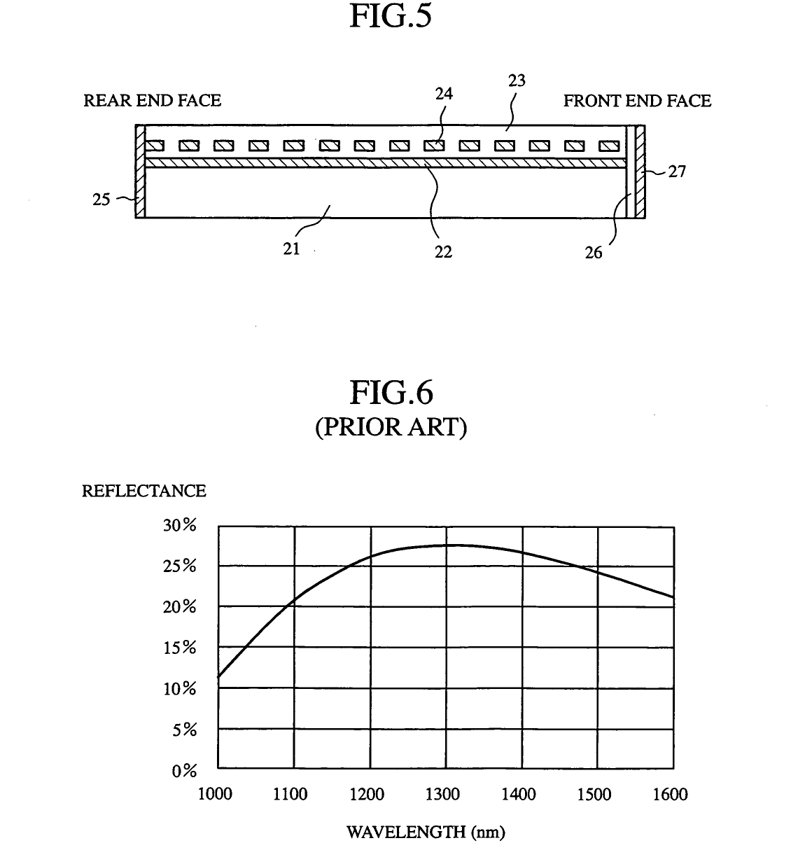

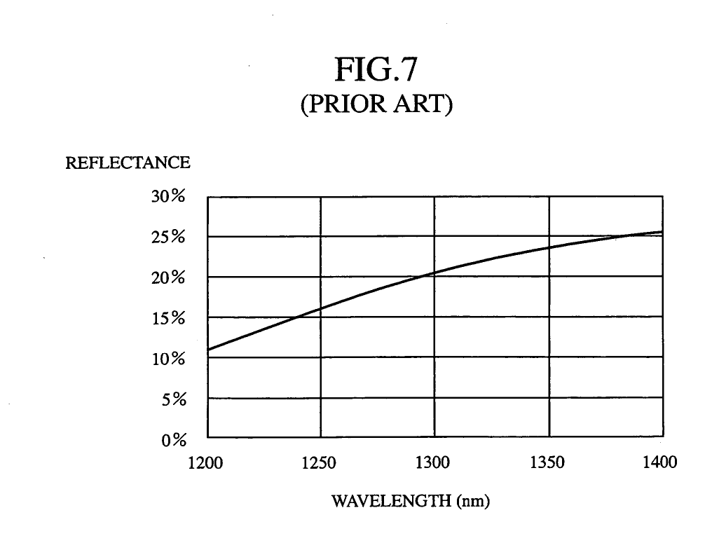

FIG. 5 is a sectional view showing the basic structure of a semiconductor laser according to embodiment 3 of the present invention.

Referring to FIG. 5, reference numeral 21 denotes a p-type InP substrate, 22 denotes an active layer formed of InGaAsP, 23 denotes a clad layer formed of n-type InP, and 24 denotes a diffraction grating formed of n-type InGaAsP, provided within the laser resonator. The reflection film 25 formed over the rear end face is a multilayer-high-reflection film having the same constitution as that of the reflection film in the above embodiment 1. The front end face thereof is provided with a first dielectric film 26 and a second dielectric film 27. The materials and the thicknesses of the dielectric films are the same as that in the above embodiment 1.

As mentioned above, according to the embodiment 3, it is arranged that the laser-beam-emitting surface of the DFB-LD having the diffraction grating within the laser resonator be provided with the multilayer film formed of the plurality of types of dielectric materials described in the embodiment 1 or embodiment 2. Therefore, the stable reflectance of the front end face serving as the laser-beam-emitting surface can be obtained against variations in the oscillation wavelength of the LD and variations in the thickness and refractive index of the dielectric film. Thereby, the noise caused by the returning light reflected from the outside of the LD can be reduced, and the DFB-LD exhibiting a narrow range of variation in the property can be obtained.

Although the multilayer film formed of two layers or three layers is described in the above embodiments, the semiconductor laser according to the present invention can be obtained by forming the multilayer film formed of a plurality of types of dielectric materials over the front end face serving as the laser-beam-emitting surface of the laser. Accordingly, when the refractive index of the multilayered i-th dielectric material is nᵢ, the film thickness thereof is dᵢ, and the emission wavelength of the laser is λ₀, respectively, it is necessary that the film thickness dᵢ satisfy the following equation (I), which is shown as a general formula.

$$\frac{m {λ}_{0}}{4} = {\sum }_{1} {n}_{i} {d}_{i} \qquad ( 1 )$$

1. A semiconductor laser having two opposed laser-beam-emitting surfaces, at least a first of the laser-beam-emitting surfaces including a multilayer dielectric film comprising a plurality of layers of different dielectric materials, wherein wavelength dependence of reflectance of the laser-beam-emitting surface has a maximum or minimum proximate the oscillation wavelength of the laser and the reflectance at the oscillation wavelength in a range from 10% to 25%.

2. The semiconductor laser according to claim 1, wherein the first laser-beam-emitting surface is a cleaved surface.

3. The semiconductor laser according to claim 1, wherein the dielectric materials of the multilayer film satisfy the following equation (I)
$$\frac{m {λ}_{0}}{4} = {\sum }_{1} {n}_{i} {d}_{i} \qquad ( 1 )$$
wherein the refractive index of the i-th dielectric material is nᵢ, the thickness of the i-th dielectric material is dᵢ, the emission wavelength of the laser is λ₀, and m is an integer.

4. The semiconductor laser according to claim 1, wherein the laser includes a diffraction grating within the laser and located between the laser-beam-emitting surfaces.
